(19) United States
(12) Patent Application Publication
(10) Pub. No.: US 2026/0279430 A1
(43) Pub. Date: Sep. 17, 2026

(54) MEMORY SYSTEM AND METHOD

(71) Applicant: Kioxia Corporation, Tokyo (JP)

(72) Inventor: Itsuki KATSUNO, Wako (JP)

(73) Assignee: Kioxia Corporation, Tokyo (JP)

(21) Appl. No.: 19/323,110

(22) Filed: Sep. 9, 2025

(30) Foreign Application Priority Data
Mar. 14, 2025 (JP) 2025-040840

(51) Int. Cl. G11C 11/4074; G11C 16/30

(52) U.S. Cl. CPC G11C 11/4074; G11C 16/30

(57) ABSTRACT

A controller executes a first discharge by causing a power supply circuit to discharge a capacitor until a voltage of the capacitor decreases by a first value. The controller calculates a second value based on a lost amount of electricity due to the first discharge and the first value. The second value is larger than the first value and smaller than a third value. The third value is a difference between a voltage of the capacitor for which charging is completed and a voltage of the capacitor in which electric energy necessary for a first operation is stored. The controller executes a second discharge by causing the power supply circuit to discharge the capacitor until a voltage of the capacitor decreases by the second value. The controller calculates a capacity of the capacitor based on a lost amount of electricity due to the second discharge and the second value.

### CROSS-REFERENCE TO RELATED APPLICATIONS

This application is based upon and claims the benefit of priority from Japanese Patent Application No. 2025-040840, filed on Mar. 14, 2025, the entire contents of which are incorporated herein by reference.

### FIELD

Embodiments described herein relate generally to a memory system and a method.

### BACKGROUND

A memory system including a nonvolatile memory and a volatile memory has been known. The nonvolatile memory functions as a storage. The volatile memory functions as a buffer for data transfer between a host and the nonvolatile memory.

The memory system may be configured to execute a power loss protection (PLP) operation. The PLP operation is an operation of saving data stored in the volatile memory into the nonvolatile memory in response to a power loss. With the PLP operation, data buffered in the volatile memory is prevented from being lost from the memory system.

In such a memory system, a capacitor is provided as a supply source of power in case of the power loss. Capacity of the capacitor decreases due to aging. Therefore, measurement of a capacity of the capacitor is timely executed during operation of the memory system in order to check whether the capacitor has a capacity capable of storing electric energy of an amount necessary for execution of the PLP operation.

### BRIEF DESCRIPTION OF THE DRAWINGS

FIG. 1 is a diagram illustrating an example of a configuration of a memory system according to an embodiment;

FIG. 2 is a diagram illustrating a data flow and a power flow in the memory system according to the embodiment while power is supplied from a host;

FIG. 3 is a diagram illustrating a data flow and a power flow in the memory system according to the embodiment when a power loss occurs;

FIG. 4 is a diagram for describing a discharge test according to the embodiment;

FIG. 5 is a diagram illustrating a change in a voltage of a PLP capacitor during a capacity measuring operation according to the embodiment; and

FIG. 6 is a flowchart illustrating the capacity measuring operation according to the embodiment.

### DETAILED DESCRIPTION

According to the present embodiment, a memory system includes a capacitor, a volatile first memory, a nonvolatile second memory, a power supply circuit, and a controller. The volatile first memory buffers first information. The power supply circuit controls charging and discharging of the capacitor. The power supply circuit is configured to execute charging of the capacitor and generation of second power by using first power while the first power is supplied from outside, and start the generation of the second power by using electric energy stored in the capacitor in response to a power loss of the first power. The controller is driven by the second power. The controller is configured to start a first operation of storing the first information buffered in the first memory into the second memory in response to the power loss, and execute a second operation of measuring a capacity of the capacitor. The second operation includes a first discharge operation of causing the power supply circuit to discharge the capacitor until a voltage of the capacitor decreases by a first value. The second operation includes an operation of calculating a second value based on an amount of electricity lost from the capacitor by the first discharge operation and the first value. The second value is larger than the first value and equal to or smaller than a third value. The third value is a difference between a voltage of the capacitor for which charging is completed and a voltage of the capacitor in which an amount of electric energy necessary for the first operation is stored. The second operation includes a second discharge operation of causing the power supply circuit to discharge the capacitor until a voltage of the capacitor decreases by the second value. The second operation includes an operation of calculating the capacity of the capacitor based on an amount of electricity lost from the capacitor by the second discharge operation and the second value.

In the following, a memory system and a method according to an embodiment will be described in detail with reference to the attached drawings. Note that the present invention is not limited by this embodiment.

### Embodiment

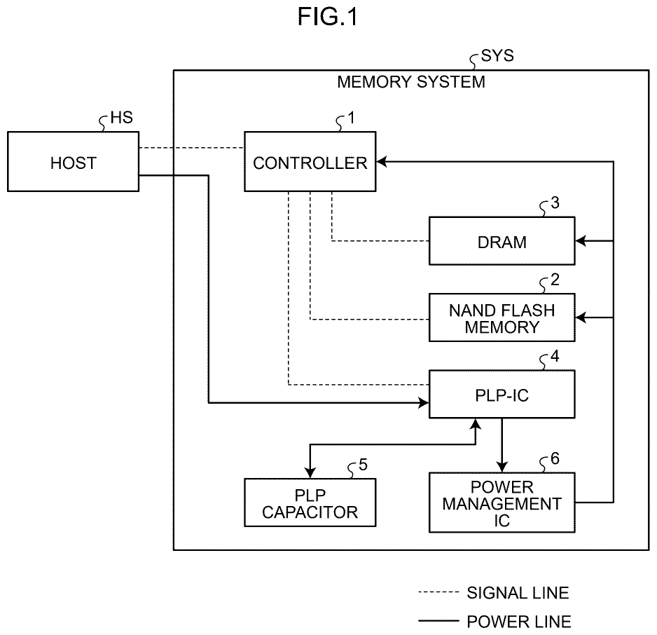

FIG. 1 is a diagram illustrating an example of a configuration of a memory system according to the embodiment.

As illustrated in FIG. 1, a memory system SYS can be connected to a host HS via a signal line and a power line. The host HS is, for example, a personal computer, a mobile information terminal, or a server. The memory system SYS can receive various requests from the host HS via the signal line. The various requests include a write request, a read request, etc. In addition, the memory system SYS receives power supply from the host HS via the power line. Note that a power supply source may not be built in the host HS. The memory system SYS may receive power supply from a device different from the host HS outside the memory system SYS.

The memory system SYS includes a controller 1, a NAND flash memory 2, a dynamic random access memory (DRAM) 3, a power loss protection-integrated circuit (PLP-IC) 4, a PLP capacitor 5, and a power management integrated circuit (power management IC) 6.

The NAND flash memory 2, the DRAM 3, and the PLP-IC 4 are each connected to the controller 1 via a signal line. The PLP-IC 4 is connected to the host HS via a power line. The PLP capacitor 5 is connected to the PLP-IC 4 via a power line. The power management IC 6 is connected to the PLP-IC 4 via a power line. Each of the controller 1, the NAND flash memory 2, and the DRAM 3 is connected to the power management IC 6 via a power line.

The NAND flash memory 2 is a storage in which data of a write request sent from the host HS is stored. Note that the storage is not limited to the NAND flash memory, and another nonvolatile memory can be optionally employed. The NAND flash memory 2 is an example of the nonvolatile second memory.

The DRAM 3 is a volatile memory used as a buffer memory, a cache memory, and a storage area in which a firmware program is loaded. The DRAM 3 is an example of the volatile first memory.

Note that the volatile memory is not limited to the DRAM 3, and another memory can be optionally employed. For example, the memory system SYS may include a static random access memory (SRAM) instead of the DRAM 3, or in addition to the DRAM 3. A part or whole of the volatile memory may be built in the controller 1.

The controller 1 controls the memory system SYS. The controller 1 includes a processor such as a central processing unit (CPU). When the processor executes the firmware program, the controller 1 implements control of the memory system SYS.

The controller 1 executes a write operation and a read operation as part of the control of the memory system SYS. The write operation is an operation of writing data of a write request sent from the host HS into the NAND flash memory 2. The read operation is an operation of reading data of a read request by the host HS, from the NAND flash memory 2 and transferring the read data to the host HS. Hereinafter, the write operation and the read operation will be collectively referred to as a host transfer operation. In addition, data of a write request from the host HS is referred to as write data, and data of a read request by the host HS is referred to as read data. The controller 1 may be implemented as a system-on-a-chip (SoC).

Moreover, the controller 1 stops the host transfer operation and executes a PLP operation in response to a power loss. The power loss refers to interruption of power supply from the host HS. The PLP operation is an operation of writing, into the NAND flash memory 2, data that is buffered in the DRAM 3 and not yet written into the NAND flash memory 2.

The PLP capacitor 5 stores electric energy used for driving of the memory system SYS after the power loss. The electric energy stored in the PLP capacitor 5 enables execution of the PLP operation. The PLP capacitor 5 includes one or more capacitors. A type of the capacitor included in the PLP capacitor 5 is not limited to a specific type. For example, the PLP capacitor 5 may include an aluminum electrolytic capacitor or a tantalum polymer capacitor.

The PLP-IC 4 is an integrated circuit configured to control charging and discharging of the PLP capacitor 5. The PLP-IC 4 receives power supply from the host HS. The PLP-IC 4 charges the PLP capacitor 5 by using the power supplied from the host HS. In addition, the PLP-IC 4 generates power by using the electric energy stored in the PLP capacitor 5 in case of the power loss. The PLP-IC 4 supplies the power supplied from the host HS or the power generated by utilization of the electric energy stored in the PLP capacitor 5 to the power management IC 6.

The power management IC 6 is an integrated circuit that generates power for driving the controller 1, the NAND flash memory 2, and the DRAM 3 by using the power supplied from the PLP-IC 4. A voltage of the power for driving the controller 1, a voltage of the power for driving the NAND flash memory 2, and a voltage of the power for driving the DRAM 3 may or may not be common.

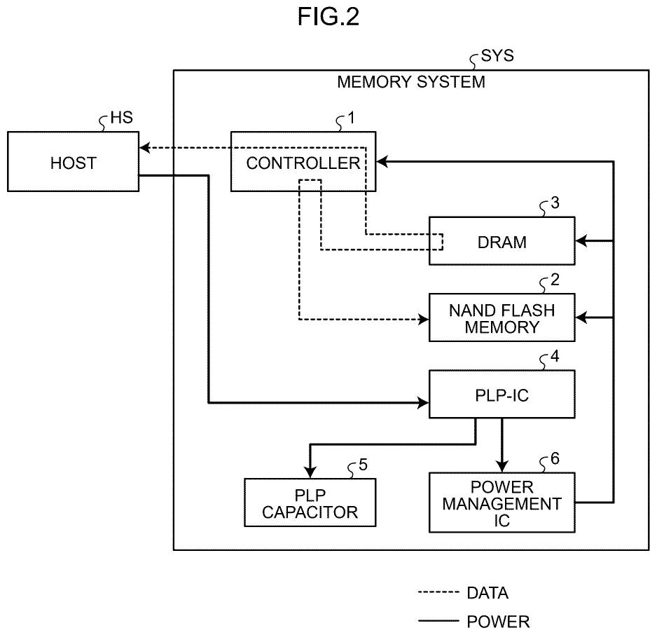

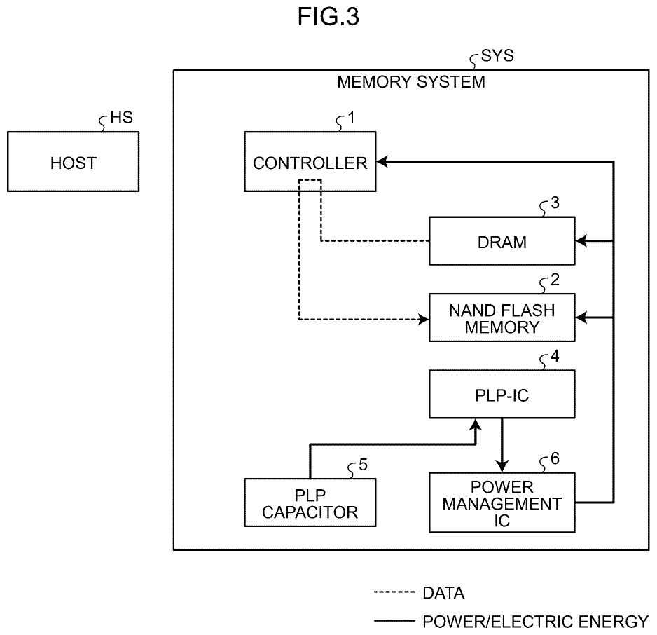

The PLP operation will be described in detail with reference to FIG. 2 and FIG. 3.

FIG. 2 is a diagram illustrating a data flow and a power flow in the memory system SYS according to the embodiment while the power is supplied from the host HS.

As illustrated in FIG. 2, while the power is supplied from the host HS, the PLP-IC 4 supplies the power supplied from the host HS to the power management IC 6. The PLP-IC 4 charges the PLP capacitor 5 by using the power supplied from the host HS.

The power management IC 6 generates power of a predetermined voltage by using the power supplied from the PLP-IC 4. Then, the power management IC 6 supplies the generated power to the controller 1, the NAND flash memory 2, and the DRAM 3.

The controller 1 is driven by the power supplied from the power management IC 6. The controller 1 executes the host transfer operation.

In the host transfer operation, the controller 1 can use the DRAM 3 as a buffer for the write data and the read data. For example, in the write operation, the controller 1 stores (that is, buffers) the write data received from the host HS in the DRAM 3, and transfers the write data stored in the DRAM 3 to the NAND flash memory 2. In the read operation, the controller 1 reads the read data from the NAND flash memory 2 and stores (that is, buffers) the read data in the DRAM 3, and transfers the read data stored in the DRAM 3 to the host HS.

FIG. 3 is a diagram illustrating a data flow and a power flow in the memory system SYS according to the embodiment when a power loss occurs.

The PLP-IC 4 generates power by using the electric energy stored in the PLP capacitor 5 and supplies the generated power to the power management IC 6.

The power management IC 6 generates power of a predetermined voltage by using the power supplied from the PLP-IC 4 similarly to when the power is supplied from the host HS. The power management IC 6 supplies the generated power to the controller 1, the NAND flash memory 2, and the DRAM 3.

The controller 1 stops the host transfer operation in response to the power loss and executes the PLP operation by using the power supplied from the power management IC 6.

In the PLP operation, the controller 1 writes pieces of data, which are buffered in the DRAM 3 and not yet written into the NAND flash memory 2, into the NAND flash memory 2.

The data written into the NAND flash memory 2 by the PLP operation includes write data that is not yet written into the NAND flash memory 2. As described above, the DRAM 3 is used as the buffer of the write data in the write operation. Thus, the write data buffered in the DRAM 3 may include the write data that is not yet written into the NAND flash memory 2. The write data that is not yet written into the NAND flash memory 2 is an object of writing to the NAND flash memory 2 in the PLP operation.

Note that the memory system SYS may be configured such that management information is cached in the DRAM 3 and the management information in the DRAM 3 is updated timely. In the PLP operation with such a configuration, the management information or updated part of the management information can also be a target of writing to the NAND flash memory 2 in the PLP operation.

A method for detecting the power loss and a method for recognizing the power loss by the controller 1 are not limited to specific methods. In one example, detection of the power loss is executed by the PLP-IC 4. The PLP-IC 4 monitors a voltage of the power line connecting the host HS and the PLP-IC 4. When the voltage of the power line falls below a threshold, the PLP-IC 4 determines that the power loss occurs. In response to the determination that the power loss occurs, the PLP-IC 4 notifies the controller 1 that the power loss occurs, and starts the generation of the power by using the electric energy stored in the PLP capacitor 5. Thus, the PLP-IC 4 and the power management IC 6 can keep generating the power for driving the memory system SYS for a while even after the power loss occurs.

Note that the PLP-IC 4 and the power management IC 6 constitute an example of the power supply circuit. As described with reference to FIG. 2 and FIG. 3, while power is supplied from the host HS, the PLP-IC 4 and the power management IC 6 charge the PLP capacitor 5 by using the power supplied from the host HS and generate power supplied to the controller 1. The PLP-IC 4 and the power management IC 6 start generating power supplied to the controller 1 by using the electric energy stored in the PLP capacitor 5 in response to the power loss, namely, interruption of power supply from the host HS.

The power supplied from the host HS is an example of the first power. The power supplied from the power management IC 6 to the controller 1 and the like is an example of the second power. In addition, data and management information buffered in the DRAM 3 and to be stored in the NAND flash memory 2 by the PLP operation are examples of the first information.

Capacity of the PLP capacitor 5 decreases due to aging. As capacity of the PLP capacitor 5 decreases, the amount of electric energy that can be stored by the PLP capacitor 5 decreases. When an amount of electric energy that can be stored in the PLP capacitor 5 is smaller than an amount of electric energy necessary for the PLP operation, completion of the PLP operation cannot be guaranteed. Therefore, the capacity of the PLP capacitor 5 is measured for checking whether the PLP capacitor 5 can store the amount of electric energy necessary for the PLP operation. During the operation of the memory system SYS, the capacity of the PLP capacitor 5 is timely measured. A trigger of the measurement of the capacity of the PLP capacitor 5 is not limited to a specific event. The capacity of the PLP capacitor 5 may be measured at predetermined time intervals. Alternatively, the capacity of the PLP capacitor 5 may be measured when performing a specific operation such as a boot operation in the memory system SYS.

In the measurement of the capacity of the PLP capacitor 5, the PLP-IC 4 discharges the PLP capacitor 5. Then, the capacity of the PLP capacitor 5 is calculated based on an amount of electricity lost from the PLP capacitor 5 by the discharge and a voltage difference in the PLP capacitor 5 before and after the discharge. Such an operation of calculating the capacity of the PLP capacitor 5 by one discharge is referred to as a discharge test.

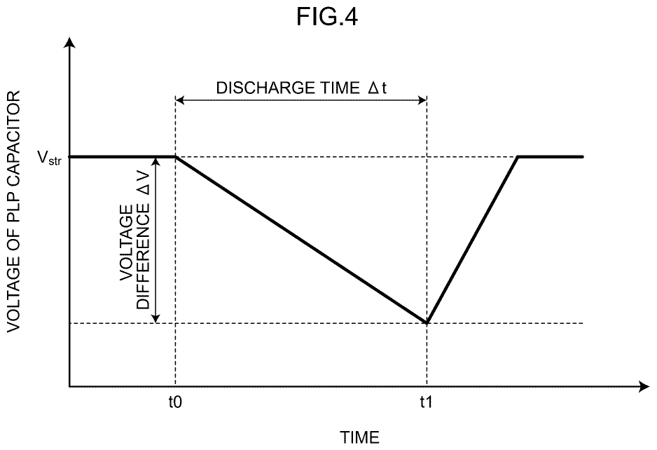

FIG. 4 is a diagram for describing the discharge test according to the embodiment. In the drawing, a horizontal axis represents time, and a vertical axis represents the voltage of the PLP capacitor 5.

In the example illustrated in FIG. 4, the PLP capacitor 5 is discharged by a constant current discharge method. The constant current discharge is a method of discharging a capacitor so as to keep a current flowing from the capacitor constant. Therefore, the amount of electricity lost from the PLP capacitor 5 can be expressed by the product of a discharge current and discharge time.

When the PLP capacitor 5 is in a fully charged state, the discharge is started (time t0). The fully charged state is a state that charging by the PLP-IC 4 has been completed. The PLP-IC 4 executes charging until the voltage of the PLP capacitor 5 reaches a set voltage (voltage Vₛₜᵣ). When the voltage of the PLP capacitor 5 reaches the set voltage Vₛₜᵣ, it is recognized that the charging is completed.

After the start of the discharge, the discharge is stopped when the voltage of PLP capacitor 5 decreases from the set voltage Vₛₜᵣ by a predetermined voltage difference ΔV (time t1). After the discharge is stopped, charging is resumed, and the voltage of the PLP capacitor 5 is recovered to the set voltage Vₛₜᵣ.

The controller 1 monitors operation of the PLP-IC 4 and acquires the time from the time t0 to the time t1 as the discharge time Δt. The discharge current is known. Thus, from the product of the discharge time Δt and the discharge current, the controller 1 acquires the amount of electricity lost from the PLP capacitor 5 by the discharge. The controller 1 then acquires the capacity of the PLP capacitor 5 by dividing the amount of electricity lost from the PLP capacitor 5 by the discharge by the voltage difference ΔV.

Specifically, the controller 1 calculates a capacity C of the PLP capacitor 5 by substituting the discharge current, the voltage difference ΔV, and the discharge time Δt into the following expression (1). In the expression (1), I_{dis} denotes the discharge current.

$$C = {I}_{d i s} \times Δ t / Δ V \qquad ( 1 )$$

A technology to be compared with the embodiment will be described. The technology to be compared with the embodiment is referred to as a comparative example. According to the comparative example, a value as small as possible is set as the voltage difference ΔV in order to enable execution of the PLP operation even when the power loss occurs during the discharge test.

In general, the smallest digit of a measured value of a physical quantity includes an error. Thus, a ratio of the error to the measured value becomes larger as the measured value becomes smaller. Conversely, a ratio of the error to the measured value becomes smaller as the measured value becomes larger.

In the discharge test, the PLP-IC measures and determines whether the voltage of the PLP capacitor decreases by the voltage difference ΔV. In the comparative example, as described above, a value as small as possible is set as the voltage difference ΔV. Therefore, a ratio of the error included in the measured value of the voltage difference ΔV to the voltage difference ΔV becomes large. Moreover, the voltage difference ΔV is small, so that the discharge time Δt is also short. Thus, an error included in the discharge time Δt is also large. A measured value of the capacity C of the PLP capacitor, which can be derived by the expression (1), may include a relatively large error. In other words, measurement accuracy of the capacity C of the PLP capacitor is poor.

As described above, the capacity of the PLP capacitor decreases due to aging. Therefore, a designer determines a rated capacity and the number of capacitors included in the PLP capacitor 5 so that the PLP operation can be executed even at last timing of a period during which the operation is guaranteed. Specifically, the designer estimates the capacity decreased due to aging, and determines the rated capacity and the number of capacitors included in the PLP capacitor 5 in such a manner that the PLP capacitor 5 has the total capacity of the minimum capacity that enables the execution of the PLP operation and the capacity decreased due to aging.

However, according to the comparative example, a measured value of a capacity of a PLP capacitor may include a relatively large error. For example, in a case where the measured value of the capacity of the PLP capacitor includes an error of a percent, the designer needs to determine the rated capacity and the number of capacitors included in the PLP capacitor in such a manner that the PLP capacitor has a capacity that is greater by an amount corresponding to a percent in addition to the sum of the minimum capacity that enables the execution of the PLP operation and the capacity decreased due to aging.

According to the comparative example, the PLP capacitor having the excessive capacity by the error of the measured value of the capacity of the PLP capacitor is mounted. As a result, a cost of the memory system increases.

Note that even in a case where the comparative example is applied, when measurement accuracy of the voltage difference ΔV is increased, measurement accuracy of the capacity of the PLP capacitor can be improved. Therefore the capacity of the PLP capacitor mounted on the memory system can be controlled. However, in order to increase the measurement accuracy of the voltage difference ΔV, it is necessary to refine the PLP-IC or to customize a general product of the PLP-IC that is generally distributed, and a large amount of cost is required.

In contrast, according to the embodiment of the present disclosure, the memory system SYS is configured to improve the measurement accuracy of the capacity of the PLP capacitor 5 without changing the PLP-IC. Specifically, the memory system SYS is configured to acquire the measured value of the capacity of the PLP capacitor 5 through two (first/second) discharge tests. In the first discharge test, the memory system SYS measures the capacity of the PLP capacitor 5 while minimizing the voltage difference ΔV as in the comparative example. In a second discharge test, the capacity of the PLP capacitor 5 is measured with the voltage difference ΔV that has been increased. The voltage difference ΔV in the second discharge test is determined based on the measured value of the capacity of the PLP capacitor 5 which value is acquired in the first discharge test. Then, the memory system SYS employs the measured value of the capacity of the PLP capacitor 5 which value is acquired by the second discharge test.

Hereinafter, the operation of measuring the capacity of the PLP capacitor 5 is referred to as a capacity measuring operation.

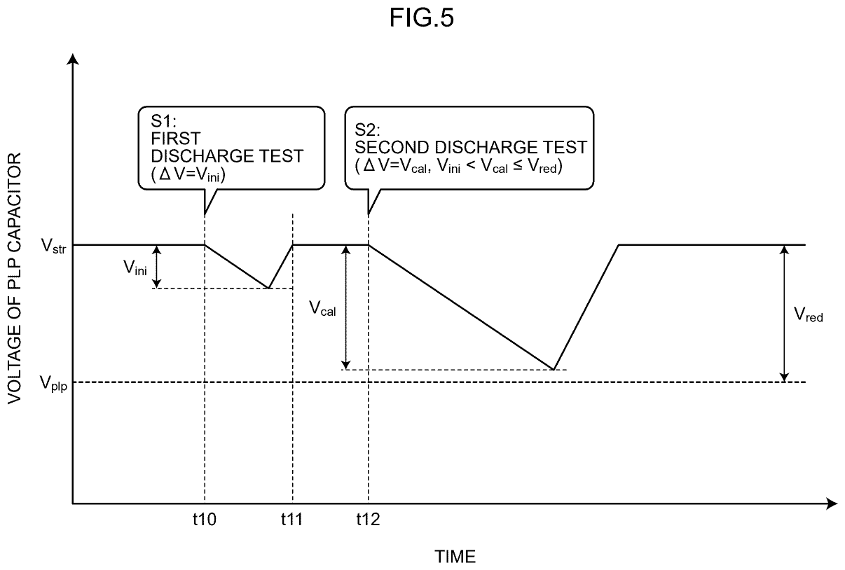

FIG. 5 is a diagram illustrating a change in the voltage of the PLP capacitor 5 during the capacity measuring operation according to the embodiment. In the drawing, a horizontal axis represents time, and a vertical axis represents the voltage of the PLP capacitor 5.

The first discharge test is started (Step S1). In Step S1, a preset voltage Vᵢₙᵢ is used as the voltage difference ΔV. In order to enable the execution of the PLP operation even when the power loss occurs in the first discharge test, a value as small as possible is set as the voltage Vᵢₙᵢ. The value of the voltage Vᵢₙᵢ may be equal to the value used as the voltage difference ΔV in the above-described comparative example.

In the example illustrated in FIG. 5, the first discharge test is started at time t10. At the time t10, the voltage of the PLP capacitor 5 starts decreasing from the set voltage Vₛₜᵣ. When the voltage of PLP capacitor 5 decreases by Vᵢₙᵢ (namely, when the voltage discharged from the PLP capacitor 5 reaches Vᵢₙᵢ), the discharge is stopped and charging is started. Then, at time t11, the voltage of the PLP capacitor 5 is recovered to the set voltage Vₛₜᵣ.

After the voltage of the PLP capacitor 5 is recovered to the set voltage Vₛₜᵣ, the second discharge test is started (Step S2). In the second discharge test, the voltage V_{cal} is used as the voltage difference ΔV. The voltage V_{cal} is higher than the voltage Vᵢₙᵢ and equal to or lower than a voltage V_{red}. The voltage V_{red} is a difference between the set voltage Vₛₜᵣ, which is the voltage of the PLP capacitor 5 in the fully charged state, and a voltage Vₚₗₚ, which is the voltage of the PLP capacitor 5 in which a minimum amount of electric energy necessary for execution of the PLP operation is stored. In the second discharge test, a value larger than that in the first discharge test is used as the voltage difference ΔV. Therefore, the capacity of the PLP capacitor 5 can be measured with higher accuracy than that in the first discharge test. Additionally, in the second discharge test, the voltage of the PLP capacitor 5 is kept to be equal to or higher than the voltage Vₚₗₚ. Therefore, the PLP operation can be executed even when the power loss occurs during the second discharge test.

Note that, in the example illustrated in FIG. 5, the second discharge test is started at time t12 that is a little after the time t11 at which the voltage of the PLP capacitor 5 is recovered to the set voltage Vₛₜᵣ. Alternatively, the second discharge test may be started immediately after the voltage of the PLP capacitor 5 is recovered to the set voltage Vₛₜᵣ.

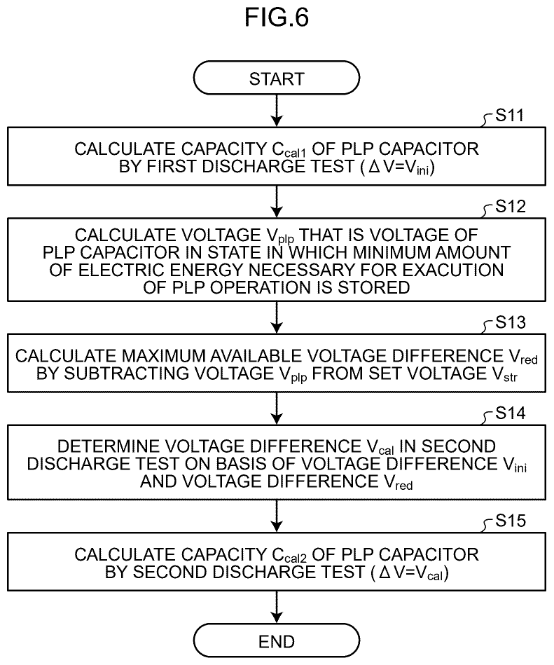

FIG. 6 is a flowchart illustrating the capacity measuring operation according to the embodiment.

The memory system SYS executes the first discharge test with the voltage Vᵢₙᵢ as the voltage difference ΔV and calculates the capacity of the PLP capacitor 5 (Step S11).

In Step S11, when the PLP capacitor 5 is in the fully charged state, the controller 1 instructs the PLP-IC 4 to discharge the PLP capacitor 5 until the voltage of the PLP capacitor 5 decreases by the voltage Vᵢₙᵢ. In response to the instruction from the controller 1, the PLP-IC 4 discharges the PLP capacitor 5 until the voltage of the PLP capacitor 5 decreases by the voltage Vᵢₙᵢ. The controller 1 acquires, as the discharge time Δt, the time taken for the discharge, namely, the time from the start of the discharge to the end of the discharge. Then, the controller 1 calculates the above-described expression (1) by using the current I_{dis}, the voltage Vᵢₙᵢ, and the discharge time Δt and acquires the measured value of the capacity of the PLP capacitor 5. The measured value of the capacity of the PLP capacitor 5 calculated in Step S11 is referred to as a capacity C_{cal1}.

Subsequently, the controller 1 calculates the voltage Vₚₗₚ that is the voltage of the PLP capacitor 5 in which the minimum amount of electric energy necessary for execution of the PLP operation is stored (Step S12).

A relationship between the amount of electric energy stored in the PLP capacitor and the voltage of the PLP capacitor is defined by the following expression (2). In the expression (2), U denotes the amount of electric energy stored in the PLP capacitor, C denotes the capacity of the PLP capacitor, and V denotes the voltage of the PLP capacitor.

$$U = C \times {V}^{2} / 2 \qquad ( 2 )$$

In Step S12, the controller 1 acquires the voltage Vₚₗₚ by substituting the amount of electric energy Uₚₗₚ necessary for the PLP operation for U in the expression (2), substituting the capacity C_{cal1} for C in the expression (2), and calculating V.

The amount of electric energy Uₚₗₚ necessary for the PLP operation is a fixed value and is known. The amount of electric energy Uₚₗₚ necessary for the PLP operation may be stored in a predetermined storage area (such as the NAND flash memory 2), and the controller 1 may read and use the amount Uₚₗₚ stored in this storage area.

Alternatively, the controller 1 may calculate the amount of electric energy Uₚₗₚ necessary for the PLP operation in some way. For example, in a case where the minimum capacity (denoted as Cₚₗₚ) of the PLP capacitor 5, which enables the execution of the PLP operation, is stored in a predetermined storage area (such as the NAND flash memory 2), the controller 1 substitutes the capacity Cₚₗₚ for C in the expression (2) and substitutes the set voltage Vₛₜᵣ for V in the expression (2), whereby the amount of electric energy Uₚₗₚ necessary for the PLP operation can be acquired.

Subsequently, the controller 1 calculates the maximum available voltage difference V_{red} by subtracting the voltage Vₚₗₚ from the set voltage Vₛₜᵣ (Step S13).

The controller 1 determines the voltage V_{cal} to be used as the voltage difference ΔV in the second discharge test, based on the voltage Vᵢₙᵢ and the voltage V_{red} (Step S14).

As long as the voltage V_{cal} is higher than the voltage Vᵢₙᵢ and equal to or lower than the voltage V_{red}, another method for determining the voltage V_{cal} can be optionally employed. In one example, the controller 1 subtracts, from the voltage V_{red}, a margin corresponding to the error included in the capacity C_{cal1}. Then, when a value acquired by the subtraction is larger than the voltage Vᵢₙᵢ, the controller 1 sets the value acquired by the subtraction as the voltage V_{cal}.

Alternatively, the controller 1 adds a first addition value to the voltage Vᵢₙᵢ. The first addition value is a value set in advance at the time of manufacturing of the memory system. When a value acquired by the addition is equal to or smaller than the voltage V_{red}, the controller 1 sets the value acquired by the addition as the voltage V_{cal}.

In a case where the value acquired by the addition is larger than the voltage V_{red}, the controller 1 adds a second addition value to the voltage Vᵢₙᵢ. The second addition value is a value set in advance at the time of manufacturing of the memory system and smaller than the first addition value. When a value acquired by the addition is equal to or smaller than the voltage V_{red}, the controller 1 sets the value acquired by the addition as the voltage V_{cal}. The memory system may have a plurality of addition values. The memory system may acquire the voltage V_{cal} by adding the addition values to the voltage Vᵢₙᵢ in an order from a larger value among the addition values until the value acquired by the addition becomes smaller than the voltage V_{red}.

Alternatively, the controller 1 may determine, in accordance with the capacity C_{cal1}, the addition value to be added to the voltage Vᵢₙᵢ. In this case, the controller 1 may have a table of addition values corresponding to the value of the capacity C_{cal1}. The table of addition values is set in advance at the time of manufacturing of the memory system. In Step S14, the controller 1 references the table of addition values based on the calculated capacity C_{cal1}. In a case where the capacity C_{cal1} is 1000 μF or less, the controller 1 determines the first addition value and adds the first addition value to the voltage Vᵢₙᵢ. In a case where the capacity C_{cal1} is 1000 μF or less, the controller 1 determines the second addition value smaller than the first addition value and adds the second addition value to the voltage Vᵢₙᵢ. The controller 1 may acquire the voltage V_{cal} in such ways.

Subsequently, the memory system SYS calculates the capacity of the PLP capacitor 5 by executing the second discharge test using the voltage V_{cal} as the voltage difference ΔV (Step S15).

In Step S15, the controller 1 instructs the PLP-IC 4 to discharge the PLP capacitor 5 until the voltage of the PLP capacitor 5 decreases by the voltage V_{cal} when the PLP capacitor 5 is in the fully charged state. In response to the instruction from the controller 1, the PLP-IC 4 discharges the PLP capacitor 5 until the voltage of the PLP capacitor 5 decreases by the voltage V_{cal}. The controller 1 acquires, as the discharge time Δt, the time taken for the discharge. Then, the controller 1 calculates the above-described expression (1) by using the current I_{dis}, the voltage V_{cal}, and the discharge time Δt and acquires the measured value of the capacity of the PLP capacitor 5. The measured value of the capacity of the PLP capacitor 5 calculated in Step S15 is referred to as a capacity C_{cal2}.

By completion of Step S15, the capacity measuring operation is ended. The controller 1 regards the capacity C_{cal2} as a measured value of the capacity of the PLP capacitor 5 and uses the capacity C_{cal2} for various kinds of control.

Note that the PLP operation is an example of the first operation. The capacity measuring operation is an example of the second operation. The operation of causing the PLP-IC 4 to discharge the PLP capacitor 5 until the voltage of the PLP capacitor 5 decreases by the voltage Vᵢₙᵢ, which is described in Step S1 of FIG. 5 and Step S11 of FIG. 6, is an example of the first discharge operation. The voltage Vᵢₙᵢ is an example of the first value. The voltage V_{cal} is an example of the second value. The voltage V_{red} is an example of the third value. The operation of causing the PLP-IC 4 to discharge the PLP capacitor 5 until the voltage of the PLP capacitor 5 decreases by the voltage V_{cal}, which is described in Step S2 of FIG. 5 and Step S14 of FIG. 6, is an example of the second discharge operation. The voltage of the PLP capacitor 5 when the PLP capacitor 5 is in the fully charged state (that is, the set voltage Vₛₜᵣ) is an example of a fourth value.

As described above, according to the embodiment, the controller 1 operates as follows in the capacity measuring operation. The controller 1 causes the PLP-IC 4 to discharge the PLP capacitor 5 until the voltage of the PLP capacitor 5 decreases by the voltage Vᵢₙᵢ. Then, the controller 1 calculates the voltage V_{cal} based on the voltage Vᵢₙᵢ and the amount of electricity lost due to the discharge executed until the voltage of the PLP capacitor 5 decreases by the voltage Vᵢₙᵢ. The voltage V_{cal} is higher than the voltage Vᵢₙᵢ and equal to or lower than the voltage V_{red}. The voltage V_{red} is a difference between the set voltage Vₛₜᵣ that is the voltage of the PLP capacitor 5 when the PLP capacitor 5 is in the fully charged state, and a voltage Vₚₗₚ that is the voltage of the PLP capacitor 5 in which the minimum amount of electric energy necessary for execution of the PLP operation is stored. Subsequently, the controller 1 causes the PLP-IC 4 to discharge the PLP capacitor 5 until the voltage of the PLP capacitor 5 decreases by the voltage V_{cal}. The controller 1 calculates the capacity C_{cal2} of the PLP capacitor 5 based on the voltage V_{cal} and the amount of electricity lost due to the discharge executed until the voltage of the PLP capacitor 5 decreases by the voltage V_{cal}.

Therefore, the capacity of the PLP capacitor 5 according to the present embodiment can be accurately measured as compared with the above-described comparative example.

In addition, according to the embodiment, the PLP-IC 4 charges the PLP capacitor 5 by using power supplied from the outside until the voltage of the PLP capacitor 5 reaches the set voltage Vₛₜᵣ. The controller 1 executes the second discharge test after the voltage of the PLP capacitor 5 is recovered to the set voltage Vₛₜᵣ after the first discharge test.

Note that start timing of the second discharge test is not necessarily after the voltage of the PLP capacitor 5 is recovered to the set voltage Vₛₜᵣ after the first discharge test. The second discharge test can be started at optional timing after the first discharge test is executed.

In addition, according to the embodiment, the controller 1 calculates the capacity C_{cal1} of the PLP capacitor 5 based on the amount of electricity lost from the PLP capacitor 5 in the first discharge test. Then, the controller 1 calculates the voltage Vₚₗₚ based on the capacity C_{cal1}.

Moreover, according to the embodiment, the PLP-IC 4 discharges the PLP capacitor 5 by the constant current discharge method in each of the first discharge test and the second discharge test.

Therefore, with the product of the current I_{dis} flowing from the PLP capacitor 5 and the discharge time Δt, the controller 1 can calculate the amount of electricity lost from the PLP capacitor 5 by the discharge.

Note that, as a method of discharging the PLP capacitor 5, a method other than the constant current discharge can be applied as long as the amount of electricity lost from the PLP capacitor 5 by discharging can be acquired by calculation.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a capacitor;
a volatile first memory buffering first information;
a nonvolatile second memory;
a power supply circuit controlling charging and discharging of the capacitor, the power supply circuit being configured to
execute charging of the capacitor and generation of second power by using first power while the first power is supplied from outside, and
start the generation of the second power by using electric energy stored in the capacitor in response to a power loss of the first power; and
a controller driven by the second power, the controller being configured to
start a first operation of storing the first information buffered in the first memory into the second memory in response to the power loss, and
execute a second operation of measuring a capacity of the capacitor, the second operation including
a first discharge operation of causing the power supply circuit to discharge the capacitor until a voltage of the capacitor decreases by a first value,
an operation of calculating a second value based on an amount of electricity lost from the capacitor by the first discharge operation and the first value, the second value being larger than the first value and equal to or smaller than a third value, the third value being a difference between a voltage of the capacitor for which charging is completed and a voltage of the capacitor in which an amount of electric energy necessary for the first operation is stored,
a second discharge operation of causing the power supply circuit to discharge the capacitor until a voltage of the capacitor decreases by the second value, and
an operation of calculating the capacity of the capacitor based on an amount of electricity lost from the capacitor by the second discharge operation and the second value.

2. The memory system according to claim 1, wherein
the power supply circuit is configured to charge the capacitor by using the first power until a voltage of the capacitor reaches a fourth value, and
the controller is configured to execute the second discharge operation after a voltage of the capacitor is recovered to the fourth value after the first discharge operation.

3. The memory system according to claim 1, wherein the controller is configured to, in the second operation,
execute a third operation of calculating the capacity of the capacitor based on the amount of electricity lost from the capacitor by the first discharge operation and the first value, and
calculate, based on the calculated capacity of the capacitor obtained by the third operation, the voltage of the capacitor in which an amount of electric energy necessary for the first operation is stored.

4. The memory system according to claim 1, wherein
the power supply circuit is configured to execute a constant current discharge in the first discharge operation and the second discharge operation, and
the controller is configured to, in the second operation,
calculate the amount of electricity lost from the capacitor by the first discharge operation based on time taken for the first discharge operation, and
calculate the amount of electricity lost from the capacitor by the second discharge operation based on time taken for the second discharge operation.

5. A memory system comprising:
a capacitor;
a power supply circuit controlling charging and discharging of the capacitor; and
a controller configured to execute
a first discharge operation of causing the power supply circuit to discharge the capacitor until a voltage of the capacitor decreases by a first value,
an operation of calculating a second value based on an amount of electricity lost from the capacitor by the first discharge operation and the first value, and
a second discharge operation of causing the power supply circuit to discharge the capacitor until a voltage of the capacitor decreases by the second value.

6. The memory system according to claim 5, wherein the controller is configured to cause the power supply circuit to recharge the capacitor before the second discharge operation starts after the first discharge operation.

7. The memory system according to claim 6, wherein the controller is configured to calculate a capacity of the capacitor based on an amount of electricity lost from the capacitor by the second discharge operation and the second value.

8. The memory system according to claim 7, further comprising:
a volatile first memory; and
a nonvolatile second memory, wherein
the power supply circuit is configured to
execute charging of the capacitor and generation of second power by using first power while the first power is supplied from outside, and
start generation of the second power by using electric energy stored in the capacitor in response to a power loss of the first power, and
the controller is configured to start a first operation of storing first information buffered in the first memory into the second memory by using the second power in response to the power loss, the second value being larger than the first value and equal to or smaller than a third value, the third value being a difference between a voltage of the capacitor for which charging is completed and a voltage of the capacitor in which an amount of electric energy necessary for the first operation is stored.

9. The memory system according to claim 8, wherein
the power supply circuit is configured to charge the capacitor by using the first power until a voltage of the capacitor reaches a fourth value, and
the controller is configured to execute the second discharge operation after a voltage of the capacitor is recovered to the fourth value after the first discharge operation.

10. The memory system according to claim 9, wherein the controller is configured to
execute a second operation of calculating a capacity of the capacitor based on the amount of electricity lost from the capacitor by the first discharge operation and the first value, and
calculate, based on the calculated capacity of the capacitor by the second operation, the voltage of the capacitor in which an amount of electric energy necessary for the first operation is stored.

11. The memory system according to claim 10, wherein
the power supply circuit is configured to execute a constant current discharge in the first discharge operation and the second discharge operation, and
the controller is configured to
calculate the amount of electricity lost from the capacitor by the first discharge operation based on time taken for the first discharge operation, and
calculate the amount of electricity lost from the capacitor by the second discharge operation based on time taken for the second discharge operation.

12. A method of controlling a memory system, the memory system including a capacitor, the method comprising:
executing a first discharge operation of discharging the capacitor until a voltage of the capacitor decreases by a first value;
calculating a second value based on an amount of electricity lost from the capacitor by the first discharge operation and the first value; and
executing a second discharge operation of discharging the capacitor until a voltage of the capacitor decreases by the second value.

13. The method according to claim 12, further comprising executing recharging of the capacitor before the second discharge operation starts after the first discharge operation.

14. The method according to claim 13, further comprising calculating a capacity of the capacitor based on the amount of electricity lost from the capacitor by the second discharge operation, and the second value.

15. The method according to claim 14, wherein
the memory system further includes a volatile first memory and a nonvolatile second memory,
the method further comprising:
executing charging of the capacitor and generation of second power by using first power while the first power is supplied from outside;
starting generation of the second power by using electric energy stored in the capacitor in response to a power loss of the first power; and
starting a first operation of storing first information buffered in the first memory into the second memory by using the second power in response to the power loss, the second value being larger than the first value and equal to or smaller than a third value, the third value being a difference between a voltage of the capacitor for which charging is completed and a voltage of the capacitor in which an amount of electric energy necessary for the first operation is stored.

16. The method according to claim 15, further comprising:
charging the capacitor by using the first power until a voltage of the capacitor reaches a fourth value; and
executing the second discharge operation after a voltage of the capacitor is recovered to the fourth value after the first discharge operation.

17. The method according to claim 16, further comprising:
executing a second operation of calculating the capacity of the capacitor based on the amount of electricity lost from the capacitor by the first discharge operation and the first value; and
calculating, based on the calculated capacity of the capacitor by the second operation, the voltage of the capacitor in which an amount of electric energy necessary for the first operation is stored.

18. The method according to claim 17, further comprising:
executing a constant current discharge in the first discharge operation and the second discharge operation;
calculating the amount of electricity lost from the capacitor by the first discharge operation based on time taken for the first discharge operation; and
calculating the amount of electricity lost from the capacitor by the second discharge operation based on time taken for the second discharge operation.

19. The method according to claim 12, further comprising executing the second discharge operation after a first time elapses after the first discharge operation is executed.

20. The memory system according to claim 1, wherein the controller is configured to execute the second discharge operation after a first time elapses after the first discharge operation is executed.
